(19) United States
(12) Patent Application Publication
(10) Pub. No.: US 2008/0298507 A1
(43) Pub. Date: Dec. 4, 2008

(54) Electronic Quadrature Device

(75) Inventors: Lucien Johannes Breems, Eindhoven (NL); Robert Rutten, Uden (NL); Derk Reefman, Best (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/096,213

(22) PCT Filed: Dec. 4, 2006
(86) PCT No.: PCT/IB2006/054572

§ 371 Date: Jun. 5, 2008

(30) Foreign Application Priority Data
Dec. 5, 2005 (EP) 05301003.9

(51) Int. Cl. H03D 1/24

(52) U.S. Cl. 375/320

(57) ABSTRACT

An electronic quadrature device is provided comprising at least one I signal path (I) and at least one Q signal path (Q); at least one first sigma-delta modulator (DSDMI) and at least one first digital/analog converter unit (DACI) arranged in the at least one I signal path (I); and at least one second sigma-delta modulator (DSDMQ) and at least one second digital/analog converter unit (DACQ) arranged in the at least one Q signal path (Q). The at least one first sigma-delta modulator (DSDMI) is coupled to the at least one second sigma-delta modulator (DSDMQ) via at least one complex signal path (C1-C4) to implement a complex filter.

### FIELD OF THE INVENTION

The present invention relates to an electronic quadrature device.

### BACKGROUND OF THE INVENTION

High resolution sigma-delta analog-to-digital (ADC) converters typically comprise multi-bit digital-to-analog converters (DAC) in the feedback path. Such DAC converters are subject to non-linearity and noise due to a mismatch of parameters which are derived from physical quantities of an integrated circuit on which the DAC is implemented. Although the resolution of a DAC can be improved by using additional bits, this will increase the mismatching problems. Accordingly, if multi-bit digital/analog converters are used the mismatching occurs in particular between different DAC elements. Hence, the sigma-delta modulators may comprise multi-bit quantizers and D/A converters to provide A/D converters with higher resolution and a higher bandwidth to increase the integration level in audio and telecommunication systems.

If delta-sigma modulators are used in the I path and the Q path of a quadrature device, IQ image leakage will be present. One solution to deal with such an IQ leakage is the usage of a dynamic element matching DEM.

U.S. Pat. No. 6,909,754 discloses a quadrature device for compensating a mismatch in parallel paths. The quadrature device comprises switching circuitry for data dependent exchanging of I and Q signals in the I and Q paths. By alternately switching the I and Q paths, the adverse effects of amplitude and phase errors resulting from possible mismatch can be reduced. In particular, a sigma-delta D/A converter in the feedback path is provided, wherein the I and Q feedback signals are exchanged.

### SUMMARY OF THE INVENTION

It is an object of the invention to provide an electronic device with a digital/analog converter with an improved matching of mismatch errors.

This object is solved by an electronic device according to claim 1.

Therefore, an electronic quadrature device is provided, which comprises at least one I signal path and at least one Q signal path. At least one first sigma-delta modulator and at least one first digital/analog converter unit are arranged in the I signal path. At least one second sigma-delta modulator and at least one second digital/analog converter unit are arranged in the Q signal path. The at least one first sigma-delta modulator is coupled to the at least one second sigma-delta modulator via at least one complex signal path to implement a complex filter.

Accordingly, a more effective noise-shaping of DAC errors can be achieved in a specific positive (or negative) frequency band.

According to an aspect of the invention the electronic quadrature device comprises a correction unit arranged in each of the at least one I signal path and at least one Q signal path for correcting the output of the sigma-delta modulators. A dynamic element matching unit performs a dynamic element matching by switching the digital/analog converter units. The outputs of the correction units are coupled to an IQ correction unit. The outputs of the correction units in the I signal path are coupled to the at least one first digital/analog converter unit. The outputs of the correction units in the Q signal path are coupled to the at least one second digital/analog converter unit. The outputs of the at least one first and second digital/analog converter units and the output of the IQ correction unit are coupled to the dynamic element matching unit. Hence, the digital/analog converter implements a complex DEM algorithm with a complex conjugate noise shaping filter for complex noise shaping of mismatch errors in a complex multi-bit sigma-delta modulator.

According to the invention, an asymmetric noise shaping is achieved by the complex filter implemented by the complex signal path between the sigma-delta modulator in the I path and the sigma-delta modulator in the Q path. The IQ image problem resulting from a mismatch between the digital/analog converters in the I path and in the Q path which are having a negative influence on the dynamic element matching and the noise shaping is dealt with by the dynamic element matching of the digital/analog converters in the I path and in the Q path. Accordingly, the IQ leakage is reduced such that image suppression for the I and Q path is improved. Furthermore, a complex noise shaping characteristic is achieved by the complex filter.

Other aspects of the invention are defined in the dependent claims.

### BRIEF DESCRIPTION OF THE DRAWINGS

The invention as well as the embodiments thereof will now be elucidated in more detail with reference to the drawings.

FIG. 1 shows a block diagram of a simple 2-bit digital analog converter DAC;

FIG. 2 shows a block diagram of a 2-bit digital/analog converter;

FIG. 3 shows a 2-bit D/A converter with a correction algorithm unit CAU;

FIG. 4 shows a graph of the output spectrum of the converter according to FIG. 3;

FIG. 5 shows part of a block diagram of a digital/analog converter according to a first embodiment;

FIG. 6 shows a graph of the output spectrum of the circuit of FIG. 5;

FIG. 7 shows part of a block diagram of a digital/analog converter according to a second embodiment;

FIG. 8 shows an output spectrum of the quadrature digital/analog converter of FIG. 7;

FIG. 9 shows part of a block diagram of a digital/analog converter according to a third embodiment; and

FIG. 10 shows a graph of the output spectrum of the digital/analog converter according to FIG. 9.

### DESCRIPTION OF THE PREFERRED EMBODIMENTS

The embodiments of the invention described below relate to a digital/analog converter DAC with sigma-delta modulators.

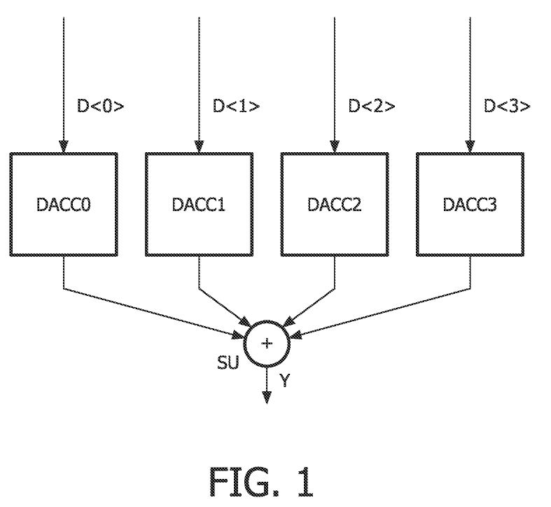

FIG. 1 shows a block diagram of a simple 2-bit digital analog converter DAC. The converter comprises 4 unit DAC cells DACC0-DACC3. The digital signal D<0:3> are input to the cells DAC0-DAC3, respectively and control the unit cells DACC0-DACC3. The output signals of the DAC cells DACC0-DACC3, which can for example be currents are added together in a summation unit SU to create the analog output signal Y. Ideally, all unit cells DACC0-DACC3 are identical. However, due to process imperfections, mismatch errors may be present among the unit DAC cells, which will result in a non-linear behavior of the DAC cells DACC0-DACC3.

To reduce the effect of mismatch, the reference sources can be controlled by digital noise-shapers. Such a technique for mismatch shaping is a data weighted averaging (DWA) as described in Norsworthy, et al., Delta-Sigma Data Converters, IEEE press, 1997, which is incorporated herein by reference.

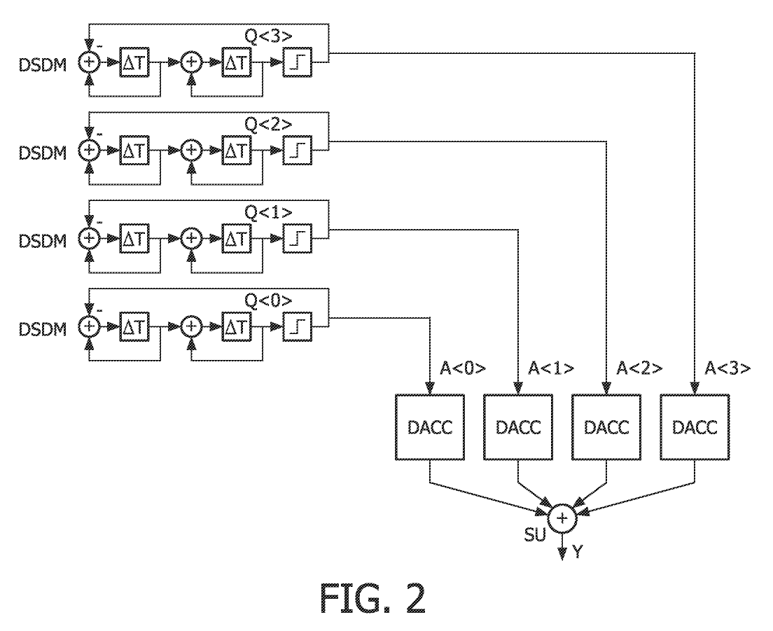

FIG. 2 shows a block diagram of a 2-bit digital/analog converter. Here, 4 DAC cells DACC are present, wherein their outputs are added together in a summation unit SU to create an analog output signal Y. A digital sigma-delta modulator DSDM is associated to each of the inputs of the DAC cells DACC. Here, 2^{nd} order 1-bit sigma-delta modulators DSDM are employed for performing a noise shaping on the mismatch errors. A digital sigma-delta modulator DSDM controls each unit cell DACC, which is free running. As a result, all sigma-delta modulators DSDM are generating noise-shaped 1-bit output signals. However, for generating the correct output signal Y that corresponds with the digital input code D<0,3>, the output code A<0,3> of the digital sigma-delta modulators has to be corrected such that the sums of A and D are equal.

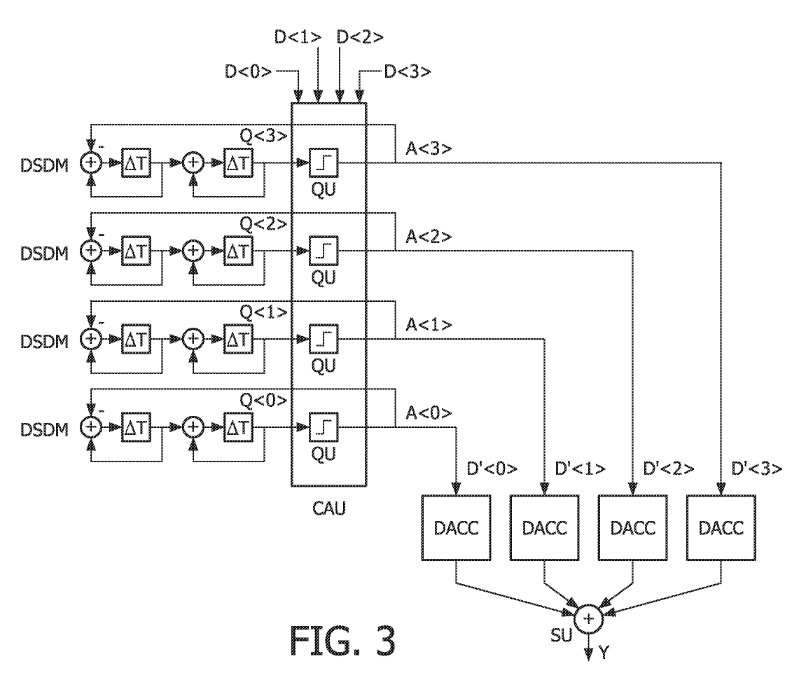

FIG. 3 shows a 2-bit D/A converter of FIG. 2 with a correction algorithm unit CAU. The correction algorithm unit CAU is arranged between the digital sigma-delta modulators DSDM and the associated DAC cells DACC, respectively. The correction algorithm unit CAU implements a correction algorithm based on the input codes Q<0>-Q<3> and D<0>-D<3> and output the codes D′<0>-D′<3>. The correction of code A<0,3> is performed to have as little impact on the noise-shaping of the digital sigma-delta modulators as possible. This can be performed by sorting the sigma-delta modulators with increasing quantizer input signal amplitudes Q <0,3>. Assuming the following example:
Q<0,3>=[−0.01 −0.4 0.25 −0.3]
A<0,3>=[0 0 1 0]
D<0,3>=[0 1 1 0]

A code A, generated by the digital sigma-delta modulators, has 3 “0” and a single “1”. The input code D of the D/A converter has two “0” and two “1”. Therefore, to correct code A<0,3>, a zero in code A needs to be changed into a “1” to have equal numbers of “0” and “1” as in D<0,3>. By changing the output code of the digital sigma-delta modulator with the smallest quantizer input amplitude (absolute value), the effect on the noise shaping is minimized. In this example Q<0> has the smallest input amplitude (0.01). After correction, code A<0,3> changes into [1 0 1 0], which now contains two zeros and two ones. Accordingly, a dynamic element matching technique is preformed.

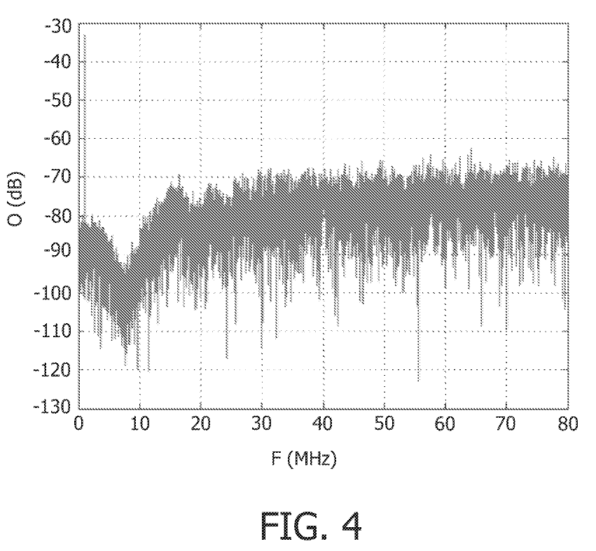

FIG. 4 shows a graph of the output spectrum of the converter according to FIG. 3. The resulting output spectrum O of the DEM algorithm with second order noise shaping of the DAC mismatch errors is shown over a frequency range F (MHz).

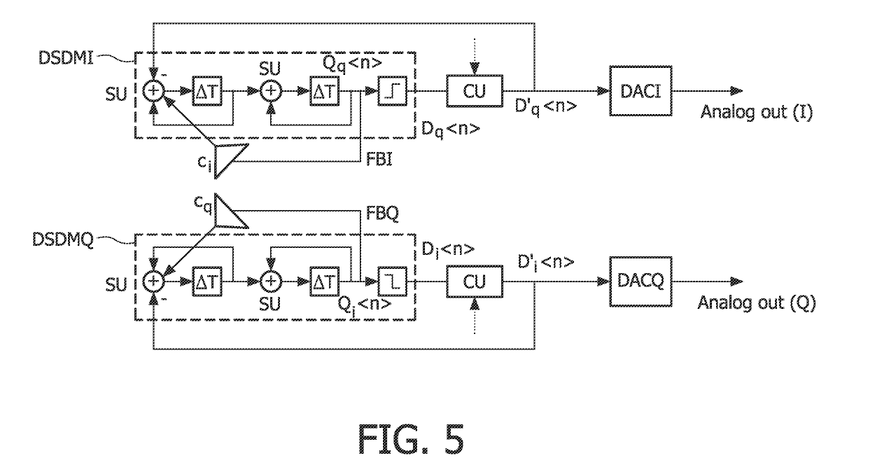

FIG. 5 shows part of a block diagram of a digital/analog converter according to a first embodiment. Here, a quadrature system with two sigma-delta modulators DSDMI, DSDMQ in a quadrature configuration is shown. It should be noted that FIG. 5 merely shows one reference cell of the I path and one reference cell of the Q path, i.e. if compared to FIG. 1, only one cell like the cell DACC0 is shown. Accordingly, in case of the two-bit DAC of FIG. 1 the system of FIG. 5 will be implemented 4 times, i.e. for each quadrature DAC cell. A correction unit CU is connected in series to the sigma-delta modulators DSDMI, DSDMQ of the quadrature configuration, respectively. In the I signal path, a digital/analog converter cell DACI is provided, and in the Q signal path, a digital/analog converter cell DACQ is provided. Each of the cells DACI, DACQ of the D/A converter of the sigma-delta modulators in the quadrature configuration is controlled by a digital sigma-delta modulator DSDMI, DSDMQ in order to implement a dynamic element matching DEM algorithm for linearization of multi-bit DAC converters in sigma-delta modulators. An I path feedback loop FBI is provided by implementing a feedback loop from before the quantizer unit QU and the summation unit SU of the digital sigma-delta modulator DSDM. In the Q signal path, a further feedback FBQ is also provided from before the quantizer unit QU to the summation unit SU. The feedback path FBI of the I path comprises a feedback coefficient CI, and the feedback path FBI of the Q signal path comprises a feedback coefficient CQ.

Accordingly, the output of each noise-shaping digital sigma-delta modulator DSDM is corrected by the correction units CU such that the output D′<0:n> corresponds to the input signal D<0:n>. Such a correction algorithm is described in more detail in “A 120 dB Multi-bit SC Audio DAC with Second-Order Noise Shaping”, by X. M. Gong et. al. (Cirrus), IEEE ISSCC 2000, p. 344-345, February 2000, which is incorporated herein by reference.

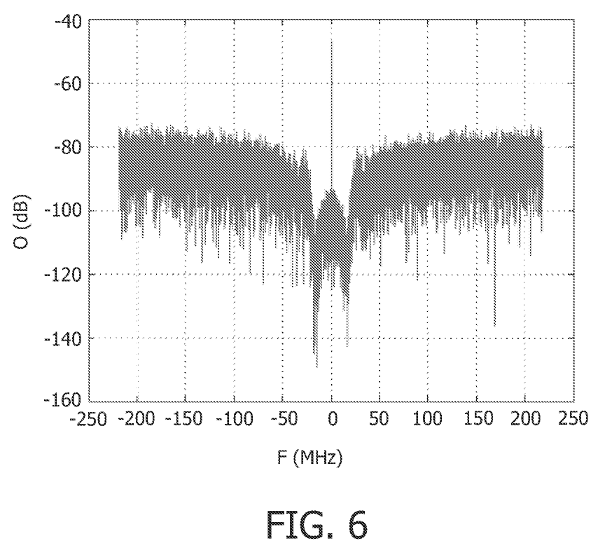

FIG. 6 shows a graph of the output spectrum of the circuit of FIG. 5 over the frequency. Here, the spectrum O is symmetric around the DC component (F=0 MHz). A notch is present in the negative as well as in the positive frequency bands. The notches are implemented by means of local feedback coefficients cᵢ and c_{q} of the feedback paths FBI, FBQ.

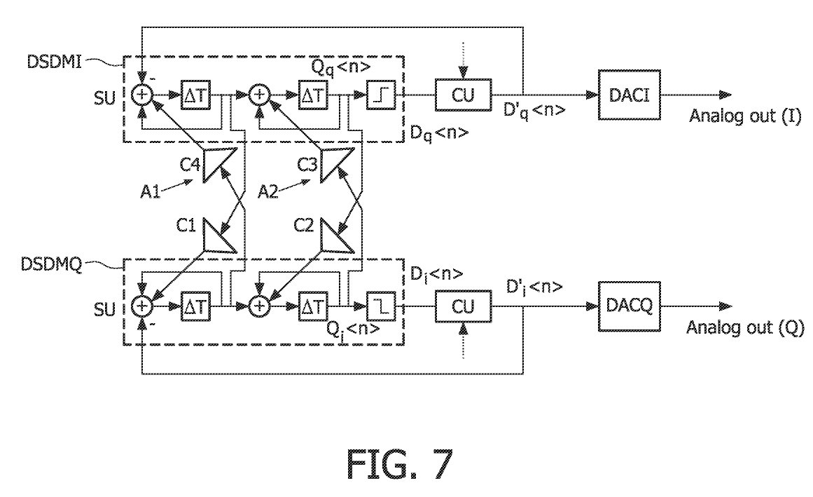

FIG. 7 shows part of a block diagram of a digital/analog converter according to a second embodiment. As in FIG. 5, the digital/analog converter according to FIG. 7 constitutes a quadrature system with two sigma-delta modulators DSDMI, DSDMQ in a quadrature configuration. Each of the digital sigma-delta modulators DSDMI, DSDMQ is coupled to a correction unit CU and to a digital/analog converter cell DACI in the I signal path and to a digital/analog converter cell DACQ in the Q signal path. In this second embodiment, quadrature paths C1-C4 are added between the digital sigma-delta modulators DSDMI, DSDMQ of the two DAC cells DACI, DACQ. With the coefficients C1-C4, an asymmetrical complex noise-shaping characteristic (Dq<n>+j*Di<n>) may be implemented by the two digital sigma-delta modulators DSDMI, DSDMQ. This may be performed for all quadrature DAC cell pairs. Accordingly, by means of the complex paths with their coefficients a more effective noise-shaping of the errors of the DAC converters can be achieved in a specific positive (or negative) frequency band.

However, the DEM scheme according to FIG. 7 has some drawbacks, as the complex noise-shaping characteristic is destroyed due to mismatch between DAC cells n_{q} and nᵢ, and as the cells of the I and Q DAC's have mismatch and noise from the image band leaks into the signal band (and vice versa).

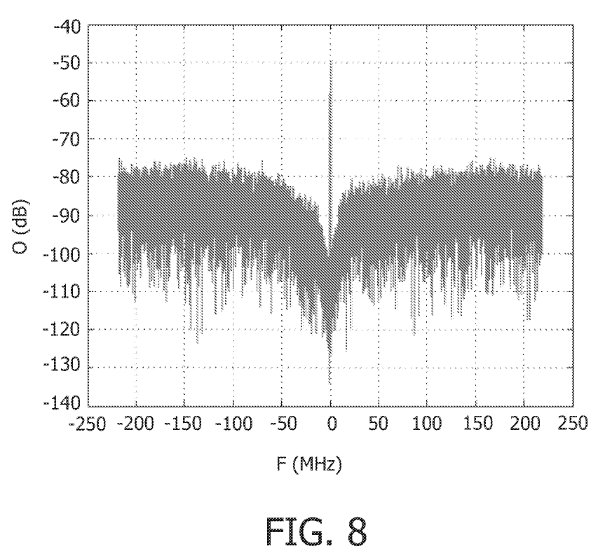

FIG. 8 shows an output spectrum of the quadrature digital-to-analog converter of FIG. 7 with mismatch between the DACI and DACQ cells. The output spectrum is very noisy and the complex noise-shaping by means of quadrature paths C1-C4 is destroyed due to the above mentioned image leakage problem.

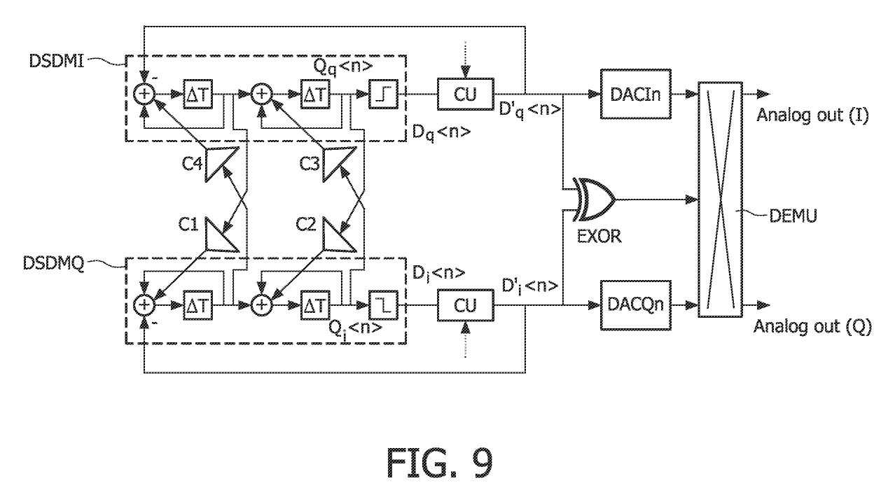

FIG. 9 shows a part of a block diagram of a digital/analog converter according to a third embodiment. As in the digital/analog converter according to FIGS. 5 and 7, here two digital sigma-delta modulators DSDMI, DSDMQ are shown which are each coupled to a correction unit, respectively. The outputs of those two correction units CU are coupled to an exclusive-OR unit EXOR. Furthermore, the outputs of the correction unit CU are connected to digital/analog converter cells DACIn and DACQd, respectively. The correction of the outputs of the digital sigma-delta modulators within the correction unit CU is performed as described according to FIG. 3. The output of the two digital/analog converter cells DACIn, DACQn and the output of the exclusive-OR EXOR are coupled to a dynamic element matching unit DEMU. However, as D_{q}<n> and Dᵢ<n> are 1-bit data streams, the image leakage problems can be solved using the DEM method as described in EP 1 183 841-B1 (in particular in paragraphs [0012]-[0019]), which is incorporated herein by reference. Accordingly, a quadrature device for compensating a mismatch in parallel paths is shown. The quadrature device comprises switching circuitry for data dependent exchanging of I and Q signals in the I and Q paths. By alternately switching the I and Q paths, the adverse effects of amplitude and phase errors resulting from possible mismatch can be reduced. Therefore, the resulting complex DEM scheme with complex DEM to solve the image leakage problem is shown. If the 1-bit signals D_{q}<n> and Dᵢ<n> are equal (both 0 or both 1), the DAC cells n_{q} and nᵢ are cross-coupled. If signals D_{q}<n> and Dᵢ<n> are different, the DAC cells n_{q} and nᵢ are coupled straight through. This way, mismatch between the two DAC cells is also noise-shaped.

The digital sigma-delta modulators DSDMI, DSDMQ in the I path and in the Q path in connection with the complex signal path serve as a noise shaper such that a one bit data stream is output by each of the sigma-delta modulators. The output of the correction unit controls the digital/analog converters DACI, DACQ. With the provision of the complex filter by the complex signal path, an asymmetric frequency spectrum can be achieved with one ore more notches in the positive or negative frequency band.

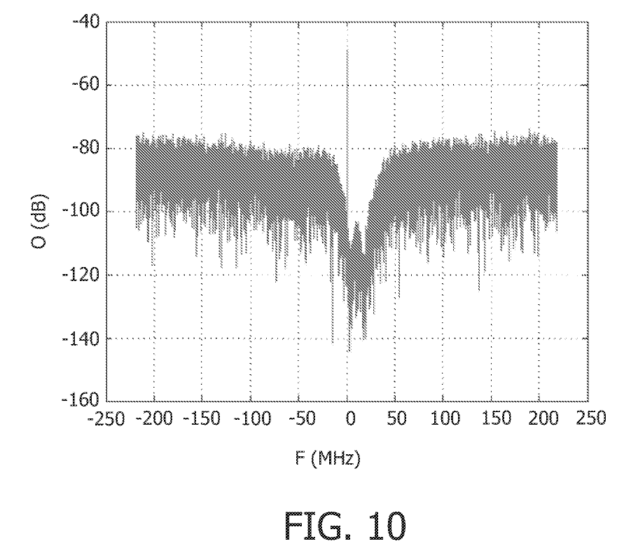

FIG. 10 shows a graph of the output spectrum of the digital/analog converter according to FIG. 9. In particular, the spectrum of the error is depicted. Accordingly, the resulting DEM scheme of FIG. 9 enables a highly efficient asymmetric quadrature noise shaping within a multi-bit complex sigma-delta modulator.

In particular, a frequency spectrum of the error between the I path and the Q path is shown. Within the range between 0 MHz and 20 MHz, the error is suppressed by the provision of the complex filter while for frequencies above 50 MHz, the error increases. Accordingly, a matching between the I path and the Q path can be performed effectively for the frequency range of 0 to 20 MHz. Furthermore, an asymmetric noise shaping is achieved as the notches in the frequency spectrum of the error occur between 0 and 20 MHz. While in FIG. 8, the notches caused by the complex filter implemented by the complex signal paths C1-C4 is covered by noise due to an image leakage between the I path and the Q path, such a leakage is significantly reduced in the frequency spectrum of FIG. 10.

The above-mentioned digital/analog converter implements a complex DEM algorithm with a complex conjugate noise shaping filter for complex noise shaping of mismatch errors in a complex multi-bit sigma-delta modulator. The complex DEM algorithm uses a IQ correction scheme as described in EP 1 183 841. The exclusive OR based exchange serves to couple the I and Q paths to the DEM unit DEMU and to perform a IQ correction. Alternatively any other IQ correction scheme may be implemented as well.

The above described DEM algorithm may be applied in a NZIF conversion system employing sigma-delta modulators for example for car radio.

The resulting DEM scheme of FIG. 9 realizes highly effective asymmetric quadrature noise-shaping (FIG. 10) in a multi-bit complex sigma-delta modulator.

The above described DAC converter with the sigma-delta modulators can be implemented in a variety of quadrature devices such as receivers, transmitters, transceivers, telephones, modulators, and demodulators.

In the above a linearization method for a complex multi-bit sigma-delta modulator is described.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

Furthermore, any reference signs in the claims shall not be constrained as limiting the scope of the claims.

1. Electronic quadrature device, comprising:
at least one I signal path and at least one Q signal path;
at least one first sigma-delta modulator and at least one first digital/analog converter unit arranged in the at least one I signal path; and
at least one second sigma-delta modulator and at least one second digital/analog converter unit arranged in the at least one Q signal path;
wherein the at least one first sigma-delta modulator is coupled to the at least one second sigma-delta modulator via at least one complex signal path to implement a complex filter.

2. Electronic quadrature device according to claim 1, comprising:
a correction unit arranged in each of the at least one I signal path and at least one Q signal path for correcting the output of the sigma-delta modulators; and
a dynamic element matching unit for performing a dynamic element matching by switching the digital/analog converter units;
wherein the outputs of the correction units are coupled to an IQ correction;
wherein the outputs of the correction units the I signal path are coupled to the at least one first digital/analog converter unit and wherein the outputs of the correction units in the Q signal path are coupled to the at least one second digital/analog converter unit; and
wherein the outputs of the at least one first and second digital/analog converter units and the output of the IQ correction unit are coupled to the dynamic element matching unit.
